(19) United States
(12) Patent Application Publication
(10) Pub. No.: US 2004/0156453 A1
(43) Pub. Date: Aug. 12, 2004

(54) Channel turbo-estimation receiver with optimized conversion

(76) Inventors: Julie Yuan-Wu, Versailles (FR); Samson Lasaulce, Crehange (FR)

Correspondence Address: LAW OFFICES OF JACOBSON HOLMAN, 400 SEVENTH STREET, N.W., WASHINGTON, DC, 20004, US

(21) Appl. No.: 10/740,686

(22) Filed: Dec. 22, 2003

(30) Foreign Application Priority Data
Dec. 20, 2002 (FR) 02/16290

(51) Int. Cl. H03D 1/00; H04L 27/06

(52) U.S. Cl. 375/340

(57) ABSTRACT

A receiver with turbo-estimation of the data transmission channel, the receiver comprising at least a channel estimator (10) and a symbol detector (20) together with a feedback loop (50) to the channel estimator (10) for returning the transmission data as estimated by the symbol detector (20) at a preceding iteration, the receiver being characterized in that the channel estimator (10) and the symbol detector (20) are designed to implement a series of operations, each resulting in an estimate being provided of at least one distinct transmitted data item, the channel estimator (10) being designed to eliminate from a group of received data items a fraction thereof which is dependent on the transmitted data item to be estimated, and on the basis of said received data from which dependency has been eliminated, to provide a determination of the propagation channel from which dependency has also been eliminated, the symbol detector (20) continuing the operation by estimating the transmitted data on the basis of said propagation channel.

The invention relates to communications based on digital transmission by data packets (packets of bits), the data being previously encoded by a channel coder (error correcting coder).

Because of propagation phenomena, the signal as transmitted is subjected to large amounts of distortion. In order to retrieve the transmitted data (information bits), it is necessary to compensate for the effects due to propagation. To do this, it is necessary to estimate propagation conditions, and more precisely it is necessary to estimate the so-called “propagation channel” which characterizes radio conditions.

The propagation channel model is a linear filter which is characterized by its impulse response. The quality with which the propagation channel is estimated has a very strong influence on the quality with which the received data is reconstituted by the receiver. It should be observed that because of noise at the receiver it is never possible to model the channel perfectly. Nevertheless, in order to obtain as good a quality of service as possible, or in order to optimize link budgets, it is fundamental to make “best efforts” in an attempt to estimate the propagation channel.

That is the object of the present invention, and this object is achieved by using a receiver with turbo-estimation of the data transmission channel, the receiver comprising at least a channel estimator and a symbol detector together with a feedback loop to the channel estimator for returning the transmission data as estimated by the symbol detector at a preceding iteration, the receiver being characterized in that the channel estimator and the symbol detector are designed to implement a series of operations each resulting in an estimate being provided of at least one distinct transmitted data item, the channel estimator being designed to eliminate from a group of received data items a fraction thereof which is dependent on the transmitted data item to be estimated, and on the basis of said received data from which dependency has been eliminated, to provide a determination of the propagation channel from which dependency has also been eliminated, the symbol detector continuing the operation by estimating the transmitted data on the basis of said propagation channel.

The invention also provides a method of processing received data, the method being of the data transmission channel turbo-estimation type, in which method use is made at least of a channel estimator and a symbol detector, together with a feedback loop for returning to the channel estimator transmitted data as estimated by the symbol detector at a preceding iteration, the method being characterized in that a series of operations are implemented, each resulting in an estimate being supplied of at least one distinct item of transmitted data, in which operation, data depending on the transmitted data item for estimation is eliminated from a group of received data items, and on the basis of said received data from which dependency has been eliminated, the channel estimator is provided with a determination of a propagation channel from which dependency has also been eliminated, with the operation being continued in the symbol detector by estimating the transmitted data item on the basis of said propagation channel.

Other characteristics, objects, and advantages of the present invention appear on reading the following detailed description made with reference to the accompanying figures, in which:

FIG. 1 shows the structure of a conventional receiver having hard or soft outputs;

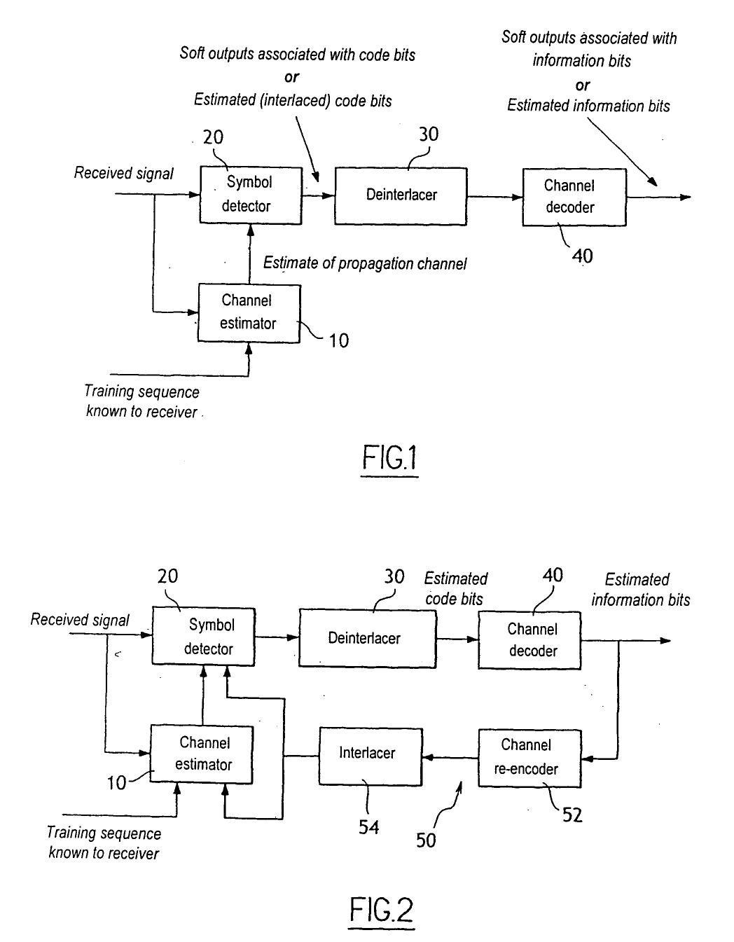

FIG. 2 shows the structure of a receiver having a turbo-estimator for a hard output;

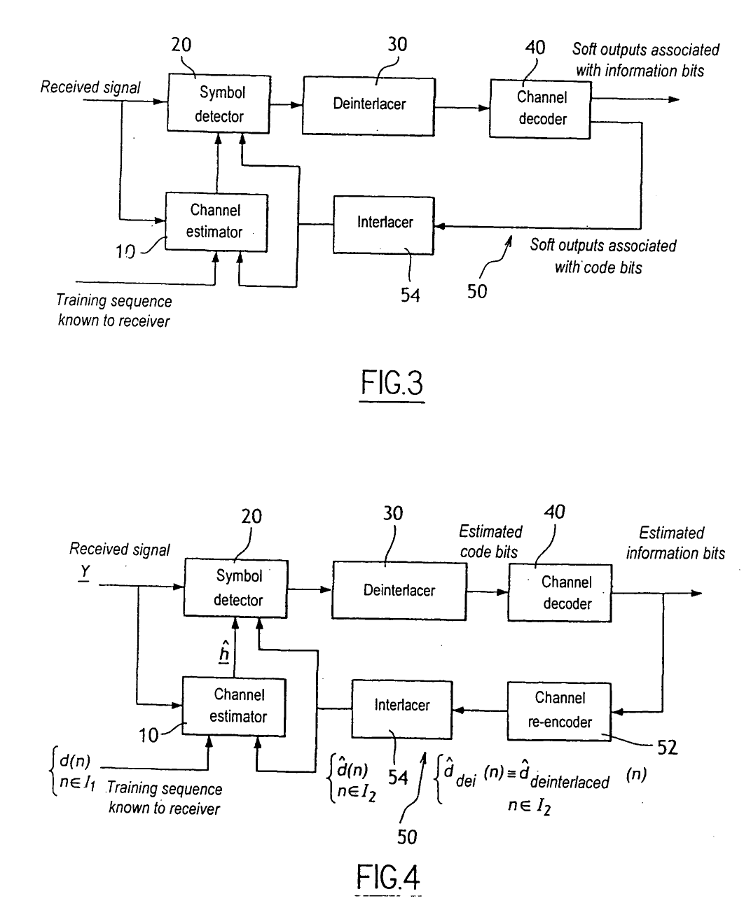

FIG. 3 shows a receiver having a turbo-estimator in accordance with a first variant of the invention, corresponding to a soft output;

FIG. 4 shows a receiver structure in accordance with another variant of the invention for a hard output;

FIG. 5 shows the same variant in accordance with the invention as shown in FIG. 3, and also shows the data using the notation implemented below; and

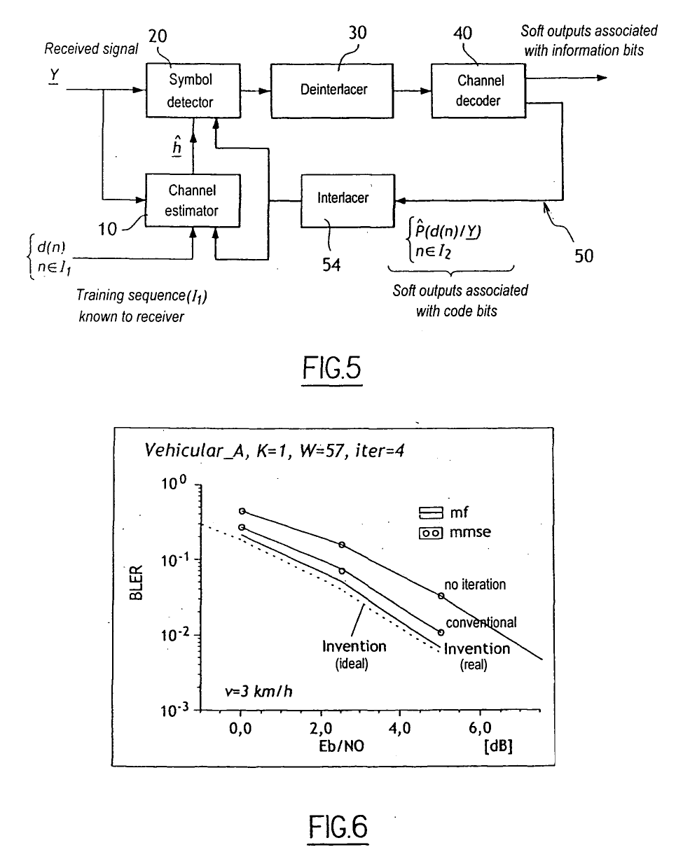

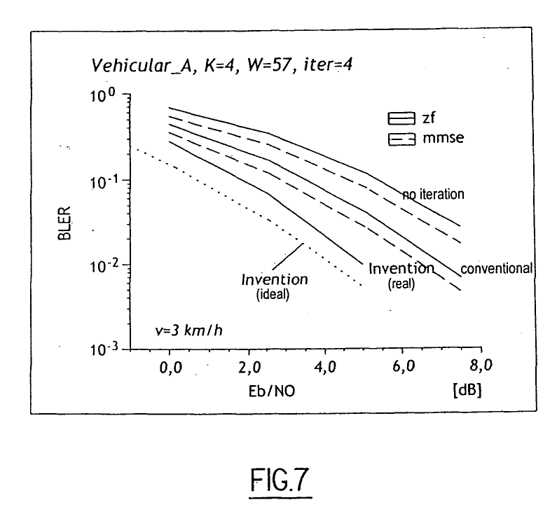

FIGS. 6 and 7 are experimental curves obtained by implementing the invention, showing a packet error rate as a function of a signal-to-noise ratio.

The proposed invention applies to any digital transmission system making use of channel estimation, and in particular to mobile radio systems and wireless local area networks (WLANs).

In particular, the proposed generic idea thus applies in non-limiting manner to time division multiple access (TDMA), code division multiple access (CDMA), time duplex CDMA (TD-CDMA), wideband CDMA (W-CDMA), orthogonal frequency division multiplexing (MC-CDMA), and multicarrier CDMA (MC-CDMA) systems, regardless of whether or not the system is in a multiple transmit multiple receive (MTMR) antenna configuration or in a multiple inputs multiple outputs (MIMO) configuration.

In the description below, attention is given more particularly to the channel-estimator portion of any iterative receiver, such as a turbo-receiver. The dispositions described are adaptable to any receiver in which channel estimation, symbol detection, and decoding are performed in iterative manner.

The general principles on which a conventional receiver operates (with digital transmission) are recalled briefly below and the principle of a turbo-receiver is described.

For a clear understanding of the operation of a conventional receiver, consideration is given to a single packet of bits that has been transmitted via the propagation channel. The packet is transmitted, then while in propagation it is subject to filtering and to noise, after which it reaches the receiver.

A conventional receiver operates as follows (FIG. 1).

From the received packet, it extracts a certain fraction (generally quite a small fraction) of the data, which fraction is referred to as the “training” sequence. This fraction comprises data which the receiver knows in advance by construction, and which serves specifically to estimate the channel. On the basis of this training fraction, the channel estimator stage 10 estimates radio conditions using a known given algorithm.

On the basis of the estimated channel, a data detection stage has a symbol detector 20 (which may be of various kinds of structure: performing linear equalization, detecting maximum likelihood, performing detection in the sense of a Posteriori maximization, performing series or parallel interference canceling, etc.) which estimates the encoded and transmitted bits/symbols on the basis of observations corresponding to the unknown fraction of the data packet, i.e. the fraction lying outside the training sequence. It should be observed that the detection operation is generally followed by a deinterlacing operation (deinterlacer 30) for inverting the interlacing that is generally introduced on transmission for the purpose of attenuating the effects of fading in the power of the received signal on the operation of the decoder.

Finally, in a decoding stage, a channel decoder 40 eliminates some of the detection errors by making use of the structure of the transmitted signal, which structure is naturally known to the receiver.

Certain types of symbol decoder and channel decoder may also have information concerning the reliability of their own outputs, in which case they are commonly referred to as a soft outputs, in contrast to hard outputs which are estimates of the transmitted bits but without their reliability.

When available, this reliability information often enables the performance of the receiver to be improved, but at an extra cost in terms of complexity which needs to be evaluated depending on circumstances. The magnitudes exchanged between the receiver stages are then as shown in FIG. 1.

In accordance with the turbo-receiver principle, it is found that the performance of the FIG. 1 receiver can be considerably improved by including a feedback loop 50 from its output.

The structure of the receiver as modified in this way is shown in FIGS. 2 and 3 for hard outputs and for soft outputs, respectively. This known receiver structure is commonly referred to as a “turbo-receiver” and it stems in part from the unanimously acclaimed work carried out by the ENST Brest on turbo-detection and turbo-equalizing.

Adding this feedback loop induces an iterative operation in the symbol detector, the channel decoder, and also the channel estimator. The description below relates mainly to the iterative channel estimator.

A turbo-receiver operates as follows.

Initially, the same steps are performed as for the conventional receiver of FIG. 1: first the propagation channel is estimated on the basis of the training sequence, the symbols (or bits) as received are detected, and the information bits are decoded.

Thereafter, the output from the decoder is reused by being re-encoded (channel re-encoder 52) and the re-encoded data is supplied to the symbol detector 20 and to the channel estimator 10. The description below relates solely to the portion involving the channel estimator 10.

It should be observed that between the re-encoder 52 and the channel estimator 10, an interlacer 54 is inserted to perform the inverse operations to those performed by the deinterlacer 30.

The channel estimator 10 thus has a further source of information in addition to the training sequence. The estimated bits coming from the re-encoder of channel 52 are used as additional training bits, it being understood that these bits contain a (small) amount of error or noise.

An operation that is additional, but not very complex on this stage, enables the performance of the receiver to be improved very significantly, thereby increasing quality of service, or enabling the power consumed by the transmitter or the receiver to be reduced (base station or mobile), thus improving the link budget of the system.

This additional operation is described below, after a few reminders concerning the notation commonly used in turbo-receivers.

To describe the invention, the notation shown in FIGS. 4 and 5 is adopted, i.e. y(n) designates the received signal, I₁ designates the interval in the bit packet corresponding to the bits of the training sequence, I₂ designates the interval that is complementary to I₁, i.e. the fraction of the received packet comprising unknown bits. In addition, the sequence d(n) corresponds to the data as transmitted and \hat{d}(n) to the estimated version thereof, given that this sequence is known completely for “n” belonging to the interval I₁ and is estimated over the interval I₂. Finally, the estimated version of the impulse response of the channel is written ĥ.

The conventional strategy [2, 3] for iterative channel estimation consists in using all of the estimated data sequence {\hat{d}(n),nεI₁∪I₂} to estimate the channel h. In mathematical terms, the observation equation of the system can be written in vector notation as follows: Y=Dh+b.

Using the notation of FIG. 4, Y designates the vector containing all of the samples of the received signal (the observations) corresponding to the entire packet of bits (Y=[y(0) . . . y(M−1)]^{T}, M being the number of symbols per packet), D designates the matrix of data transmitted over the channel, h is the true impulse response of the channel, and b is the noise vector.

Thus, for a given iteration, the conventional channel estimation strategy consists in using the latest estimate of the data matrix \hat{D} and the entire observation vector Y to obtain the channel estimate ĥ.

The performance of the (so-called “conventional”) reference method described above that is in widespread use saturates at a level which cannot be exceeded, even for an infinite number of operations.

Nevertheless, in the context of the present invention, it turns out that this “barrier” can be exceeded if certain precautions are taken in the way in which estimated data is used by the channel estimator.

In this case, use is not made of all of the observations of the received signal, i.e. certain samples are excluded from the vector Y in order to perform channel estimation.

In order to find the portion that is to be excluded, it is necessary to consider the output from the symbol detector and each symbol for estimation in individual manner.

Thus, in order to detect the symbol of index “n”, it is necessary previously to have estimated the channel on the basis of all of the observations that are independent of the symbol of index “n”.

Dependent observations, i.e. observations that are to be excluded from the observation vector, can be obtained immediately from the one-dimensional version of the observation equation:

$$∀ m ∈ {[ 0 , M - 1 ]}_{N} , y ( m ) = {\sum }_{i = 0}^{i = l - 1} h ( i ) d ( m - i ) + b ( m )$$

which means that for given “n”, the symbol “d(n)” is associated with the observation “y(n), y(n+1), . . . y(n+l−1)”, where l is the length of the impulse response of the channel.

Consequently, we propose excluding these observations from the observation vector which is used for the channel estimation that is performed immediately beforehand.

It should be observed that eliminating the dependency of channel estimation relative to the symbol(s) that are/is to be found by using this estimate is a step which applies to any type of channel estimator (including estimators based on the expectation maximization (EM) algorithm [6, 7]) and in particular for the estimator that is the most widespread, being the pseudo-inverse of the data matrix “\hat{D}” (this estimator is described below in the context of the preferred implementation of the present invention).

In particular, this operation consisting in eliminating the above-mentioned dependency can, in some cases (the most usual cases), be represented mathematically by the following substitution:

$$\underline{Y} -> \underline{Y} - [ \begin{matrix}{0}_{-} \\ y ( n ) \\ ⋮ \\ y ( n + l - 1 ) \\ {0}_{-}\end{matrix} ]$$

The consequence of acting in this way to create independence between the symbol(s) to be detected and the channel estimate used for performing the detection, which in the particular case described above is implemented by a substitution operation, is to prevent the error portion in the channel estimate propagating, which error portion otherwise has the effect of “saturating” the convergence process in the symbol detector downstream from the channel estimator.

One solution for improving the convergence of the iterative turbo-reception procedure lies specifically in performing the above-proposed substitution.

By performing the proposed operation, it is shown in the experimental portion of this specification (see below) that a significant improvement in the performance of the turbo-receiver can be obtained. However, in the particular case where creating independence involves the above-explained substitution, the manner in which this operation is implemented is also of great importance since that determines the amount of additional complexity that is due to this operation.

The description below proposes a good configuration that enables the extra cost in terms of complexity to be very reasonable.

The invention described above can be implemented in various ways. A particular way of implementing the method in practice is described below for the purpose of describing a particularly advantageous physical structure for the invention which is proposed for the purpose of obtaining a small amount of additional complexity in the channel estimation stage of the receiver.

Firstly, the symbol “d(n)” is detected for the “p^{th}” detection while at that time eliminating from the preceding channel estimate those observations “y(.)” that are dependent on the symbol “d(n)”.

In a manner that is the most usual, but that is entirely general, the channel estimate is obtained by pseudo-inversion of the data matrix “\hat{D}” containing the symbols of the training sequence and the estimated information symbols. This is written as follows:

ĥ=\hat{D}^{#}Y=(\hat{D}^{H}\hat{D})⁻¹ \hat{D}^{H}Y

The exponent H designates the operation of transposition and conjugation. The exponent # designates the pseudo-inversion operation. To detect the symbol “d(n)”, it is necessary in this case for each “n” under consideration in the current distinct step, to subtract from “Y” the portion that depends on “d(n)”.

It should be observed that these distinct steps of estimating a selected symbol d(n) can be implemented at different iterations of the turbo-estimation loop (for example the successive symbols d(n) can be estimated at successive iterations).

It should also be observed that the updated estimates of distinct symbols d(n) can be performed in the same iteration of the turbo-estimation loop, using distinct estimates of the propagation channel for each distinct symbol d(n).

Writing the number of symbols to be detected per packet (or per slot or per frame) as “N”, where N is also the size of the interval I₂ in the notation introduced above, it can be seen that it is necessary to perform “N” pseudo-inversions of “\hat{D}” in order to obtain as many channel estimates “ĥₙ^{(new)}” to be used for detecting symbols.

One idea for considerably reducing the calculation cost involved consists in rewriting the estimate in the following form:

$$\begin{matrix}'' {\hat{\underline{h}}}_{n}^{( new )} '' = {( {\hat{D}}^{H} \hat{D} )}^{- 1} {\hat{D}}^{H} [ \underline{Y} - [ \begin{matrix}{0}_{-} \\ y ( n ) \\ ⋮ \\ y ( n + l - 1 ) \\ {0}_{-}\end{matrix} ] ] \\ = {( {\hat{D}}^{H} \hat{D} )}^{- 1} {\hat{D}}^{H} \underline{Y} - {( {\hat{D}}^{H} \hat{D} )}^{- 1} {\hat{D}}^{H} [ \begin{matrix}{0}_{-} \\ y ( n ) \\ ⋮ \\ y ( n + l - 1 ) \\ {0}_{-}\end{matrix} ]\end{matrix}$$

Thus identifying the variable portion that actually needs to be calculated in order to obtain the channel estimate as follows:

$$δ \underline{{h}_{n}} = {\hat{D}}^{H} [ \begin{matrix}{0}_{-} \\ y ( n ) \\ ⋮ \\ y ( n + l - 1 ) \\ {0}_{-}\end{matrix} ]$$

we observe that it is not necessary to perform the “N” pseudo-inversions of the matrix “\hat{D}” and that for each symbol “d(n)” it suffices to update the vector “δh” in the channel estimate used for decoding the symbol. In summary, the proposed algorithm can be implanted in a manner that is written as follows for a given iteration:

∀n ε I₂, ĥₙ^{(new)}=ĥ−(\hat{D}^{H}\hat{D})⁻¹δhₙ

where “ĥ”, which is the initial channel estimate, and “(\hat{D}^{H}\hat{D})⁻¹” both need to be calculated once only, and finally “δhₙ” is the variable portion that needs to be calculated for each symbol “d(n)”.

In this variant, a plurality of estimates “ĥₙ^{(new)}” are thus calculated for different indices n in the same iteration of the turbo-estimation loop, so as to make use of the same matrix “(\hat{D}^{H}\hat{D})⁻¹” several times over, where “\hat{D}” is the matrix of the data d(n) estimated at the preceding iteration.

The symbol detector 20 also performs a plurality of calculations in a same loop iteration, consisting in calculating the various d(n) using their respective estimates “ĥₙ^{(new)}”.

Thus, the symbol detector 20 updates a plurality of different values of d(n) in the matrix “\hat{D}”, thereby renewing the matrix “\hat{D}”.

The matrix is then reused a plurality of times in the following iteration for calculating a plurality of different “ĥₙ^{(new)}” in this following iteration.

The invention described above can be used in association with various data detectors (or symbol detectors). A particularly advantageous use of the invention consists in associating the proposed channel estimator with an interference canceling symbol detector, and in particular with those that are known at present.

The two dispositions described above (eliminating dependencies and calculating “δhₙ”) relate to improving the turbo-estimator. These dispositions can be applied to any iterative receiver, preferably with a dependency-eliminating symbol detector.

It should be observed that calculating “δhₙ” can be used (implemented at low cost) independently of using an interference canceler.

Similarly, an interference canceler can be used in the context of eliminating dependencies independently of calculating “δhₙ” as proposed above.

Nevertheless, maximum performance in terms of minimizing complexity cost is obtained when all of the above-proposed dispositions are used in association.

It is therefore proposed to use an interference-canceling detector for symbol detection.

Thus, it is therefore proposed to associate selecting the proposed turbo-estimation technique with a symbol detector whose purpose is to cancel partially or totally the interference caused either by the multi-path channel, i.e. interference between chips or symbols (inter-chip interference (ICI) or inter-symbol interference (ISI)), or (inclusive or) by interference caused by the presence of other users, i.e. multiple access interference (MAI) or multiuser interference (MUI).

Various examples of practical applications are described below.

We have applied the proposed idea to the time division duplex (TDD) mode of the universal mobile telecommunications system (UMTS) which is a TD-CDMA system. The characteristics of the services tested and the system under consideration were as follows:

service 12.2 kilobit per second (kbit/s);

uplink (mobile to base station);

number of symbols per packet (or slot): 2×122=244 quadrature phase shift keyed (QPSK) symbols, giving a total of 488 bits per slot;

CDMA code spreading factor: Q=8;

training sequence length: 512 chips;

channel encoding: convolutional coding with a ratio of ⅓;

one packet per 10 millisecond (ms) frame;

propagation environment: International Telecommunications Union (ITU) “Vehicular A” channel; and

assumed channel length: 57 chips.

The symbol detectors used were the linear block equalizers described in [3] and referred to as “Zero-forcing block linear joint detector” (ZF in the figures) and “Minimum mean square error block linear joint detector” (MMSE in the figures); these detectors are those that are recommended by the TDD standard.

Reference is made to FIG. 6. The corresponding simulations were performed for one active user per time slot, i.e. network loading of 12.5% (spreading factor of 8 restricting the maximum number of active users to 8).

The six curves in the figure represent the packet error rate (BLER: block error rate) as a function of the signal-to-noise ratio (Eb/No). These curves show mainly (from top to bottom):

the performance of the matched filter (MF) without iteration (continuous line);

the performance of the MMSE block equalizer without iteration (three measurement points represented by three circles);

the performance of the matched filter MF with four iterations (continuous line marked “conventional”) using the conventional channel estimation strategy;

the performance of the MMSE block equalizer with four iterations (three measurement points represented by three circles);

the performance of the matched filter MF with four iterations (continuous line marked “invention: real”) using the proposed channel estimation strategy; and

the performance of the matched filter MF with four iterations (in dashed lines marked “invention: ideal”) for the ideal case in which it is possible to provide the channel estimator with true data (no error).

In FIG. 6, it can be seen that the invention (“invention: real”) provides a gain of 0.5 decibels (dB) to 0.6 dB in signal-to-noise ratio compared with a conventional turbo-estimator (“conventional”).

By considering a more common circumstance in which the network has 50% loading, i.e. four active users per slot, this gain increases to about 2 dB (FIG. 7) and that constitutes gain that is considerable.

There follow a few more details about the conditions under which the simulations corresponding to FIG. 7 were carried out. Given the loading of the network, it was no longer assumed that the filter was matched since multiple access interference is considerable under such circumstances. For example only zero forcing (ZF) and MMSE detectors were considered.

The important comparison to observe in this figure is the comparison between the third curve from the top (conventional channel estimation strategy) and the fifth curve from the top (proposed strategy). This shows the 2 dB gain mentioned above.

[1] M. Sandell et al., “Iterative channel estimation using soft decision feedback”, Proc. Blobecom '98, pp. 3728-3733, December 1998.

[2] P. Strauch et al., “Iterative channel estimation for EGPRS”, Proc. IEEE VTC'2000 Fall, pp. 2271-2277, September 2000.

[3] A. Klein, G. Kaleh, P. Baier, “Zero forcing and minimum mean-square-error equalization for multiuser detection in CDMA channels”, IEEE Transactions on Vehicular Technology, May 1996.

1. A receiver with turbo-estimation of the data transmission channel, the receiver comprising at least a channel estimator (10) and a symbol detector (20) together with a feedback loop (50) to the channel estimator (10) for returning the transmission data as estimated by the symbol detector (20) at a preceding iteration, the receiver being characterized in that the channel estimator (10) and the symbol detector (20) are designed to implement a series of operations, each resulting in an estimate being provided of at least one distinct transmitted data item, the channel estimator (10) being designed to eliminate from a group of received data items a fraction thereof which is dependent on the transmitted data item to be estimated, and on the basis of said received data from which dependency has been eliminated, to provide a determination of the propagation channel from which dependency has also been eliminated, the symbol detector (20) continuing the operation by estimating the transmitted data on the basis of said propagation channel.

2. A receiver according to claim 1, characterized in that the channel estimator (10) is designed to determine the propagation channel (10) from which dependency has been eliminated both on the basis of said data from which dependency has been eliminated and from said transmitted data as estimated at a preceding iteration of turbo-estimation and supplied to the channel estimator (10) via the feedback loop (50).

3. A receiver according to claim 2, characterized in that in order to establish different estimates of the propagation channel (“ĥₙ^{(new)}”) each corresponding specifically to estimating a different item of transmitted data, the channel estimator (10) uses the same vector (ĥ) and subtracts from this same vector a vector that is specific on each occasion ((\hat{D}^{H}\hat{D})⁻¹\hat{D}^{H}δhₙ), this vector which is specific on each occasion being constituted mainly by received data which does depend on the data to be estimated.

4. A receiver according to claim 3, characterized in that the channel estimator (10) is designed to calculate each specific vector for subtracting in the propagation channel calculation in the form of a product between a constant matrix (\hat{D}^{H}\hat{D})⁻¹\hat{D}^{H}) and a vector of data that is excluded (δhₙ) since it depends on d(n)

5. A receiver according to any preceding claim, characterized in that the channel estimator (10) makes use, for the various transmitted symbols to be estimated d(n) of a calculated channel estimate ĥₙ from which dependency has been eliminated, in the form:
ĥₙ=ĥ−A.δhₙ
where ĥ is an identical vector for each of the symbols d(n) to be estimated, A is an identical matrix used for the various symbols d(n) to be estimated, and δhₙ is a vector constituted mainly by data that has been received by the receiver and that is dependent on the transmitted symbol to be estimated d(n).

6. A receiver according to claim 5, characterized in that:
$$δ \underline{{h}_{n}} = {\hat{D}}^{H} [ \begin{matrix}{0}_{-} \\ y ( n ) \\ ⋮ \\ y ( n + l - 1 ) \\ {0}_{-}\end{matrix} ]$$
where the y-terms are data received by the receiver, \hat{D}^{H}is a transform of the matrix \hat{D} of the transmitted data as estimated at a preceding iteration of turbo-estimation, and the propagation channel is considered as being a linear transformation, “l” being the length of said linear transformation and also corresponding to the length of the propagation channel.

7. A receiver according to any preceding claim, characterized in that the symbol detector (20) is an interference-canceling detector.

8. A receiver according to the preceding claim, characterized in that the interference-canceling symbol detector (20) is designed to reduce interference caused by a multi-path channel (ICI, ISI).

9. A receiver according to claim 7 or claim 8, characterized in that the interference-canceling symbol detector (20) is designed to reduce interference caused by other users (MAI, MUI).

10. A method of processing received data, the method being of the data transmission channel turbo-estimation type, in which method use is made at least of a channel estimator (10) and a symbol detector (20), together with a feedback loop (50) for returning to the channel estimator (10) transmitted data as estimated by the symbol detector (20) at a preceding iteration, the method being characterized in that a series of operations are implemented, each resulting in an estimate being supplied of at least one distinct item of transmitted data, in which operation, data depending on the transmitted data item for estimation is eliminated from a group of received data items, and on the basis of said received data from which dependency has been eliminated, the channel estimator (10) is provided with a determination of a propagation channel from which dependency has also been eliminated, with the operation being continued in the symbol detector (20) by estimating the transmitted data item on the basis of said propagation channel.
